(19) United States
(12) Patent Application Publication
(10) Pub. No.: US 2024/0298507 A1
(43) Pub. Date: Sep. 5, 2024

(54) DISPLAY PANEL, METHOD FOR MANUFACTURING SAME, DISPLAY DEVICE, AND VEHICLE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Xing Huang, Beijing (CN); Xin Mou, Beijing (CN)

(21) Appl. No.: 17/800,254

(22) PCT Filed: Oct. 25, 2021
(86) PCT No.: PCT/CN2021/126188

§ 371 Date: Aug. 17, 2022

(30) Foreign Application Priority Data
Feb. 25, 2021 (CN) 202110214298.6

(51) Int. Cl. H10K 59/80; H10K 59/35

(52) U.S. Cl. CPC H10K 59/876; H10K 59/35

(57) ABSTRACT

Provided is a display panel. The display panel includes a base substrate; and a total reflection electrode layer, a light-emitting layer, a semi-reflection electrode layer, a first resonance layer, and a second resonance layer which are sequentially laminated in a direction distal from the base substrate, wherein the first resonance layer is configured to reflect first light and allow second light to pass through; the second resonance layer is configured to reflect third light and allow fourth light to pass through; all of the first light, the second light, the third light, and the fourth light are light passing through the semi-reflection electrode layer; and a refractive index of the first resonance layer is different from a refractive index of the second resonance layer.

### CROSS-REFERENCE TO RELATED APPLICATION

This application is a 371 of PCT application No. PCT/CN2021/126188, filed on Oct. 25, 2021, which claims priority to the Chinese Patent Application No. 202110214298.6, filed on Feb. 25, 2021 and entitled “DISPLAY PANEL, METHOD FOR MANUFACTURING SAME, DISPLAY DEVICE, AND VEHICLE,” the disclosures of which are incorporated herein by reference in their entirety.

### TECHNICAL FIELD

The present disclosure relates to the field of display technologies, and in particular, to a display panel, a method for manufacturing the same, a display device, and a vehicle.

### BACKGROUND

Organic light-emitting diode (OLED) display panels have been widely applied due to their characteristics of self-luminance, low drive voltage, fast response, and the like.

### SUMMARY

The present disclosure provides a display panel, a method for manufacturing the same, a display device, and a vehicle.

According to some embodiments of the present disclosure, a display panel is provided. The display panel includes:
a base substrate; and
a total reflection electrode layer, a light-emitting layer, a semi-reflection electrode layer, a first resonance layer, and a second resonance layer which are sequentially laminated in a direction distal from the base substrate,
wherein the first resonance layer is configured to reflect first light and allow second light to pass through; the second resonance layer is configured to reflect third light and allow fourth light to pass through; all of the first light, the second light, the third light, and the fourth light are light passing through the semi-reflection electrode layer; and a refractive index of the first resonance layer is different from a refractive index of the second resonance layer.

In some embodiments, the refractive index of the first resonance layer is less than the refractive index of the second resonance layer.

In some embodiments, the refractive index of the first resonance layer ranges from 1.6 to 1.7; and the refractive index of the second resonance layer ranges from 1.8 to 1.9.

In some embodiments, a material of the first resonance layer is different from a material of the second resonance layer;
and/or, a thickness of the first resonance layer is different from a thickness of the second resonance layer.

In some embodiments, both the materials of the first resonance layer and the second resonance layer are inorganic materials.

In some embodiments, the materials of the first resonance layer and the second resonance layer each include at least one of silicon nitride and silicon oxynitride.

In some embodiments, wherein a total of a thickness of the first resonance layer and a thickness of the second resonance layer ranges from 1.7 μm to 2.1 μm.

In some embodiments, the thickness of the first resonance layer ranges from 1 μm to 1.2 μm; and the thickness of the second resonance layer ranges from 0.7 μm to 0.9 μm.

In some embodiments, a total of a thickness of the first resonance layer and a thickness of the second resonance layer ranges from 1.8 μm to 2.3 μm.

In some embodiments, the display panel comprises a plurality of light-emitting units; the total reflection electrode layer comprises a plurality of total reflection patterns; and the light-emitting layer comprises a plurality of light-emitting patterns which corresponds to the plurality of total reflection patterns in one-to-one correspondence; and

each total reflection pattern, a light-emitting pattern corresponding to the total reflection pattern, and the semi-reflection electrode layer form one light-emitting unit.

In some embodiments, the plurality of light-emitting units comprise a red light-emitting unit, a green light-emitting unit, and a blue light-emitting unit; the first resonance layer comprises a plurality of first resonance patterns which corresponds to the plurality of light-emitting units in one-to-one correspondence; an orthographic projection of each first resonance pattern onto the base substrate covers an orthographic projection of a light-emitting region of a light-emitting unit corresponding to first resonance pattern onto the base substrate; the second resonance layer comprises a plurality of second resonance patterns which corresponds to the plurality of light-emitting units in one-to-one correspondence; and an orthographic projection of each second resonance pattern onto the base substrate covers an orthographic projection of a light-emitting region of a light-emitting unit corresponding to the second resonance pattern onto the base substrate; and
a total thickness of one first resonance pattern and one second resonance pattern which cover the red light-emitting unit, a total thickness of one first resonance pattern and one second resonance pattern which cover the green light-emitting unit, and a total thickness of one first resonance pattern and one second resonance pattern which cover the blue light-emitting unit differ from each other.

In some embodiments, the total thickness of the first resonance pattern and the second resonance pattern which cover the red light-emitting unit is greater than the total thickness of the first resonance pattern and the second resonance pattern which cover the green light-emitting unit; and
the total thickness of the first resonance pattern and the second resonance pattern which cover the green light-emitting unit is greater than the total thickness of the first resonance pattern and the second resonance pattern which cover the blue light-emitting unit.

In some embodiments, the display panel further includes a light-extracting layer disposed between the semi-reflection electrode layer and the first resonance layer; and
the light-extracting layer is configured to transmit, the light passing through the semi-reflection electrode layer, to the first resonance layer.

In some embodiments, a thickness of the light-extracting layer ranges from 150 nm to 300 nm; and the light-extracting layer is made of organic material.

In some embodiments, the display panel further comprises a planarization layer disposed on a side, distal from the base substrate, of the second resonance layer; and
the refractive index of the first resonance layer is less than a refractive index of the light-extracting layer and the refractive index of the second resonance layer; and the refractive index of the second resonance layer is less than a refractive index of the planarization layer.

In some embodiments, the refractive index of the light-extracting layer ranges from 1.7 to 2.0; and the refractive index of the planarization layer ranges from 1.9 to 2.1.

In some embodiments, the display panel further includes a packaging film layer; and
the packaging film layer is disposed on the side, distal from the base substrate, of the second resonance layer.

In some embodiments, the packaging film layer includes a first packaging layer, a second packaging layer, and a third packaging layer which are sequentially laminated in the direction distal from the base substrate;
the first packaging layer is made of an inorganic material; a thickness of the first packaging layer ranges from 500 nm to 1500 nm; and a refractive index of the first packaging layer ranges from 1.6 to 1.9;
the second packaging layer is made of organic material; a thickness of the second packaging layer ranges from 8 μm to 15 μm; and a refractive index of the second packaging layer ranges from 1.1 to 1.8; and
the third packaging layer is made of an inorganic material; a thickness of the third packaging layer ranges from 500 nm to 1500 nm; and a refractive index of the third packaging layer ranges from 1.6 to 1.9.

In some embodiments, the total reflection electrode layer includes a first film layer, a second film layer, and a third film layer which are sequentially laminated in the direction distal from the base substrate; and
both the first film layer and the third film layer are made of indium tin oxide; and a reflectivity of the second film layer is greater than 80%.

In some embodiments, a reflectivity of the semi-reflection electrode layer ranges from 20% to 30%; and a material of the semi-reflection electrode layer includes at least one of magnesium, silver, and aluminum.

In some embodiments, the display panel further comprises a third resonance layer disposed on the side, distal from the base substrate, of the second resonance layer; and
the third resonance layer is configured to reflect fifth light and allow sixth light to pass through, wherein the fifth light and the sixth light are light passing through the semi-reflection electrode layer; and a refractive index of the third resonance layer is different from both the refractive index of the first resonance layer and the refractive index of the second resonance layer.

According to some embodiments of the present disclosure, a method for manufacturing a display panel is provided. The method includes:
providing a base substrate; and
sequentially forming a total reflection electrode layer, a light-emitting layer, a semi-reflection electrode layer, a first resonance layer, and a second resonance layer in a direction distal from the base substrate,
wherein the first resonance layer is configured to reflect first light and allow second light to pass through; the second resonance layer is configured to reflect third light and allow fourth light to pass through; all of the first light, the second light, the third light, and the fourth light are light passing through the semi-reflection electrode layer; and a refractive index of the first resonance layer is different from a refractive index of the second resonance layer.

According to some embodiments of the present disclosure, a display device is provided. The display device includes a power supply assembly and the display panel according to the above aspects, wherein
the power supply assembly is configured to supply power to the display panel.

According to some embodiments of the present disclosure, a vehicle is provided. The vehicle includes a vehicle body and the display device according to the above aspect and disposed in the vehicle body.

### BRIEF DESCRIPTION OF THE DRAWINGS

For clear descriptions of the technical solutions in the embodiments of the present disclosure, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of a display panel according to some embodiments of the present disclosure;

FIG. 2 is a schematic structural diagram of another display panel according to some embodiments of the present disclosure;

FIG. 3 is a top view of a display panel according to some embodiments of the present disclosure;

FIG. 4 is a schematic diagram of light in a display panel according to some embodiments of the present disclosure;

FIG. 5 is a schematic diagram of a spectrum according to some embodiments of the present disclosure;

FIG. 6 is a schematic diagram of another spectrum according to some embodiments of the present disclosure;

FIG. 7 is a schematic diagram of a color cast curve according to some embodiments of the present disclosure;

FIG. 8 is a schematic diagram of a brightness attenuation curve according to some embodiments of the present disclosure;

FIG. 9 is a schematic structural diagram of still another display panel according to some embodiments of the present disclosure;

FIG. 10 is a schematic structural diagram of a total reflection electrode layer according to some embodiments of the present disclosure;

FIG. 11 is a schematic structural diagram of yet another display panel according to some embodiments of the present disclosure;

FIG. 12 is a schematic structural diagram of yet another display panel according to some embodiments of the present disclosure;

FIG. 13 is a schematic structural diagram of yet another display panel according to some embodiments of the present disclosure;

FIG. 14 is a flowchart of a method for manufacturing a display panel according to some embodiments of the present disclosure;

FIG. 15 is a flowchart of another method for manufacturing a display panel according to some embodiments of the present disclosure;

FIG. 16 is a schematic diagram of forming a pixel definition layer according to some embodiments of the present disclosure;

FIG. 17 is a schematic structural diagram of a display device according to some embodiments of the present disclosure; and

FIG. 18 is a schematic structural diagram of a vehicle according to some embodiments of the present disclosure.

### DETAILED DESCRIPTION

For clearer descriptions of the objectives, technical solutions, and advantages of the present disclosure, embodiments of the present disclosure are described in detail below with reference to the accompanying drawings.

In a display panel known to the inventors, the display panel includes a reflection electrode, a semi-reflection electrode, and a light-emitting layer between the reflection electrode and the semi-reflection electrode. After being repeatedly reflected between the reflection electrode and the semi-reflection electrode, light emitted by the light-emitting layer is emergent from a side, distal from the reflection electrode, of the semi-reflection electrode. Light reflected between the reflection electrode and the semi-reflection electrode interferes with each other, thereby increasing the intensity of emergent light and further improving the display effect of the display device.

However, the quantity of times by which the light is reflected between the reflection electrode and the semi-reflection electrode is limited. As a result, interference of the reflected light can obviously improve neither the intensity of the emergent light nor the display effect of the display device.

In “European vehicle standards” (for example, Display Specification for Automotive Application Version 5.0), the main wavelength and saturation of a vehicle-mounted display panel are strictly specified. The hue of red is required to be crimson, that is, the main wavelength of red light in light emergent from the display panel is required to reach 623 nm (nanometer). However, in a process of manufacturing a vehicle-mounted display panel according to the display panel known to the inventors, both the efficiency and service life of the vehicle-mounted display panel need to be taken into consideration. As a result, red displayed by the display panel is hard to be deep; and the main wavelength of red light in light emergent from an existing vehicle-mounted display panel can reach 616 nm at most.

In the display panel known to the inventors, a display panel in a display device uses a top emission device structure to improve the display effect of the display device. The display panel includes a reflection electrode, a semi-reflection electrode, and a light-emitting layer between the reflection electrode and the semi-reflection electrode. After being repeatedly reflected between the reflection electrode and the semi-reflection electrode, light emitted by the light-emitting layer is emergent from a side. distal from the reflection electrode, of the semi-reflection electrode.

Because an internal resonant micro-cavity effect exists between the reflection electrode and the semi-reflection electrode (that is, light is repeatedly reflected between the reflection electrode and the semi-reflection electrode), the cavity length of an internal resonant cavity can be adjusted only by adjusting the thickness of the light-emitting layer. In this way, the photon distribution of a specific light wave can be adjusted; the main wavelength of red light in light emergent from the display panel can be increased; and the chroma of the red light emergent from the display panel can be adjusted.

However, adjusting the main wavelength of the red light emergent from the display panel by adjusting the thickness of the light-emitting layer usually causes a problem of frequency doubling; and only light corresponding to some wavelengths can be emergent efficiently. As a result, the degree of adjusting a light color in an resonant internal micro-cavity fashion is limited. Currently, the main wavelength of red light can be increased to a certain extent by adjusting the thickness of the light-emitting layer. For example, it can be learned via analog simulation that currently, the main wavelength of red light can be increased to 619 nm by adjusting the thickness of a light-emitting layer. This indicates that the requirement in “European vehicle standards” is still not met. In addition, a light-emitting layer is usually manufactured in a process of performing vacuum evaporation on organic light-emitting material. Therefore, evaporation duration is prolonged when the thickness of the light-emitting layer is adjusted. As a result, the manufacture cost is higher. Moreover, brightness attenuation and a color cast occur in a display panel to a certain extent due to thickness adjustment of the light-emitting layer, causing a poorer display effect of the display device.

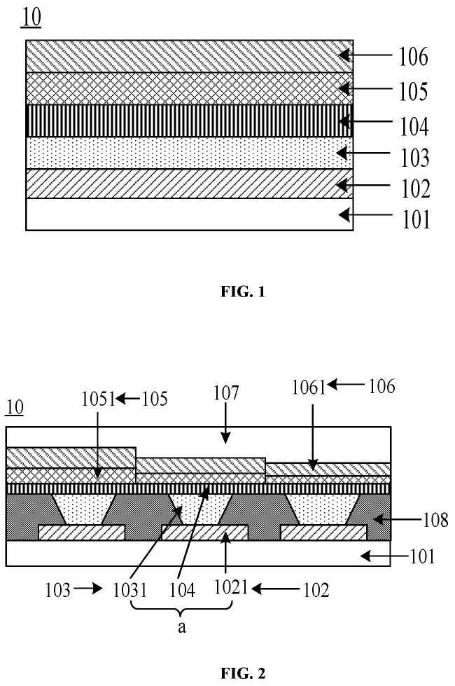

FIG. 1 is a schematic structural diagram of a display panel according to some embodiments of the present disclosure. Referring to FIG. 1, it can be learned that the display panel 10 includes a base substrate 101, as well as a total reflection electrode layer 102, a light-emitting layer 103, a semi-reflection electrode layer 104, a first resonance layer 105, and a second resonance layer 106 which are sequentially laminated in a direction distal from the base substrate 101.

In some embodiments of the present disclosure, the light-emitting layer 103 in the display panel 10 emits light. The light is repeatedly reflected between the total reflection electrode layer 102 and the semi-reflection electrode layer 104 and be emergent from the semi-reflection electrode layer 104. In other words, the total reflection electrode layer 102 is configured to reflect the light emitted by the light-emitting layer 103; and the semi-reflection electrode layer 104 is configured to reflect the light emitted by the light-emitting layer 103, and allow the light to pass through.

The first resonance layer 105 and the second resonance layer 106 are disposed on a side, distal from the base substrate 101, of the semi-reflection electrode layer 104. Therefore, after being repeatedly reflected between the semi-reflection electrode layer 104 and the total reflection electrode layer 102 and passing through the semi-reflection electrode layer 104, the light emitted by the light-emitting layer 103 is irradiated on the first resonance layer 105 and the second resonance layer 106. The first resonance layer 105 is configured to reflect first light and allow second light to pass through. The second resonance layer 106 is configured to reflect third light and allow fourth light to pass through. All of the first light, the second light, the third light, and the fourth light are the light passing through the semi-reflection electrode layer 104. The refractive index of the first resonance layer 105 is different from the refractive index of the second resonance layer 106.

The first light reflected by the first resonance layer 105 is different from the second light passing through the first resonance layer 105. In some embodiments, the included angle between the first light and a bearing surface of the base substrate 101 is different from the included angle between the second light and the bearing surface of the base substrate 101. The third light reflected by the second resonance layer 106 is different from the fourth light passing through the second resonance layer 106. In some embodiments, the included angle between the third light and the bearing surface of the base substrate 101 is different from the included angle between the fourth light and the bearing surface of the base substrate 101.

Because the first resonance layer 105 and the second resonance layer 106 are disposed on the side, distal from the base substrate 101, of the semi-reflection electrode layer 104, and the refractive index of the first resonance layer 105 is different from the refractive index of the second resonance layer 106, the first light passing through the semi-reflection electrode layer 104 is reflected by the first resonance layer 105, and the third light passing through the semi-reflection electrode layer 104 is reflected by the second resonance layer 106. The reflected light is reflected again by the semi-reflection electrode layer 104, or enters space between the semi-reflection electrode layer 104 and the total reflection electrode layer 102 after passing through the semi-reflection electrode layer 104 and continue being reflected between the semi-reflection electrode layer 104 and the total reflection electrode layer 102. In other words, after being emergent from the semi-reflection electrode layer 104, the light continues being repeatedly reflected among the semi-reflection electrode layer 104, the total reflection electrode layer 102, the first resonance layer 105, and the second resonance layer 106. Being reflected for many times, the light has a great mutual interference effect. Therefore, the intensity and chroma of emergent light can be substantially improved and adjusted, which can better improve the display effect of the display device. In other words, the display effect of the display device is better.

In summary, the embodiments of the present disclosure provide a display panel. According to the display panel, a first resonance layer and a second resonance layer are disposed on a side, distal from a base substrate, of a semi-reflection electrode layer, such that after passing through the semi-reflection electrode layer, light emitted by a light-emitting layer is repeatedly reflected among the semi-reflection electrode layer, a total reflection electrode layer, the first resonance layer, and the second resonance layer. Because the display panel is provided with the first resonance layer and the second resonance layer, the mutual interference effect of light reflected in the display panel can be improved. Therefore, the intensity and chroma of light emergent from the display panel can be substantially improved and adjusted, thereby effectively improving the display effect of the display device.

FIG. 2 is a schematic structural diagram of another display panel according to some embodiments of the present disclosure. Referring to FIG. 2, the display panel includes a plurality of light-emitting units a. FIG. 2 shows three light-emitting units a. Each light-emitting unit a is configured to emit light. The light emitted by the light-emitting unit a is repeatedly reflected between the semi-reflection electrode layer 104 and the total reflection electrode layer 102, thereby implementing an internal resonant micro-cavity effect on the light emitted by the light-emitting unit a.

In some embodiments, the plurality of light-emitting units a include a red (R) light-emitting unit, a green (G) light-emitting unit, and a blue (B) light-emitting unit.

In the embodiments of the present disclosure, the first resonance layer and the second resonance layer are used as a cavity body part of an external resonant cavity of the light-emitting units in the display panel 10, thereby implementing an external resonant micro-cavity effect on the light emitted by the light-emitting units, further adjusting the spectrum of the light emitted by the light-emitting units, and adjusting the chroma of light emitted by light-emitting units of different colors.

In some embodiments, the display panel 10 in the present disclosure is applied to a vehicle. Because “European vehicle standards” specifies a certain requirement for the main wavelength of red light in light emergent from a vehicle-mounted display panel, i.e., the main wavelength of the red light in the light emergent from the display panel needs to reach 623 nm. To meet the above requirement, a display device disposed in the vehicle includes the display panel 10 in the embodiments of the present disclosure, thereby increasing the chroma of the red light emitted by the light-emitting unit. Therefore, the main wavelength of the red light emitted by the red light-emitting unit is increased.

Because “European vehicle standards” specifies a certain requirement for the main wavelength of red light in light emergent from a vehicle-mounted display panel, i.e., the main wavelength of the red light in the light emergent from the display panel needs to reach 623 nm. To meet the above requirement, referring to FIG. 3, the first resonance layer 105 and the second resonance layer 106 are disposed on a side, distal from the base substrate 101, of the red light-emitting unit. Therefore, the chroma of the light emitted by the red light-emitting unit can be adjusted.

In some embodiments, referring to FIG. 3, the first resonance layer 105 and the second resonance layer 106 are disposed on neither a side, distal from the base substrate 101, of the green light-emitting unit nor a side, distal from the base substrate 101, of the blue light-emitting unit. In some other embodiments, the first resonance layer 105 and the second resonance layer 106 are disposed on the side, distal from the base substrate 101, of the green light-emitting unit and/or the side, distal from the base substrate 101, of the blue light-emitting unit. This is not limited in the embodiments of the present disclosure.

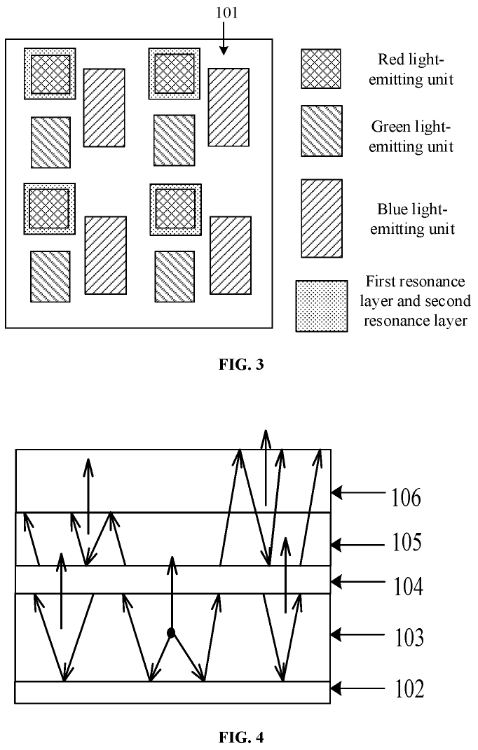

Referring to FIG. 4, the third light passing through the semi-reflection electrode layer 104 is reflected by an interface between the first resonance layer 105 and the second resonance layer 106. The reflected light enters the space between the semi-reflection electrode layer 104 and the total reflection electrode layer 102, and be repeatedly reflected between the semi-reflection electrode layer 104 and the total reflection electrode layer 102, wherein light reflected at different moments interferes with each other. In this way, a first external resonant micro-cavity effect of the first resonance layer 105 and the second resonance layer 106 is implemented.

The fourth light passing through the semi-reflection electrode layer 104 is refracted by the interface between the first resonance layer 105 and the second resonance layer 106. The refracted light is reflected, distal from the base substrate 101, by a side of the second resonance layer 106. The reflected light enters the space between the semi-reflection electrode layer 104 and the total reflection electrode layer 102, or space between the first resonance layer 105 and the semi-reflection electrode layer 104. In addition, the reflected light is repeatedly reflected between the semi-reflection electrode layer 104 and the total reflection electrode layer 102, or between the first resonance layer 105 and the semi-reflection electrode layer 104, wherein light reflected at different time interferes with each other. In this way, a second external resonant micro-cavity effect of the first resonance layer 105 and the second resonance layer 106 is implemented.

Based on the above analysis, it can be learned that in addition to the internal resonant micro-cavity effect between the semi-reflection electrode layer 104 and the total reflection electrode layer 102, the display panel 10 in the embodiments of the present disclosure also implements the first external resonant micro-cavity effect and the second external resonant micro-cavity effect. Because the micro-cavity effect of the display panel 10 in the embodiments of the present disclosure is enhanced, the spectrum of the light emergent from the display panel can acquire a certain gain (The main wavelength of the emergent light is increased).

For example, the red light emergent from the display panel can acquire a certain gain (The main wavelength of the red light is increased). Therefore, the color of the red light emergent from the display panel can be deeper, thereby meeting the requirement of “European vehicle standards”.

In the embodiments of the present disclosure, the refractive index of the first resonance layer 105 is less than the refractive index of the second resonance layer 106. Because the first resonance layer 105 is more proximal to the semi-reflection electrode layer 104 than the second resonance layer 106 is, light emergent from the semi-reflection electrode layer 104 first passes through the first resonance layer 105, and then pass through the second resonance layer 106. By designing the refractive index of the first resonance layer 105 to be less than the refractive index of the second resonance layer 106, light can be refracted conveniently by the interface between the second resonance layer 106 and the first resonance layer 105, thereby guaranteeing the display effect of the display device.

In some embodiments, the refractive index of the first resonance layer 105 ranges from 1.6 to 1.7; and the refractive index of the second resonance layer 106 ranges from 1.8 to 1.9.

In the embodiments of the present disclosure, to ensure that the refractive index of the first resonance layer 105 is different from the refractive index of the second resonance layer 106, the material of the first resonance layer 105 is different from the material of the second resonance layer 106; or the thickness of the first resonance layer 105 is different from the thickness of the second resonance layer 106; or the material of the first resonance layer 105 is different from the material of the second resonance layer 106, and the thickness of the first resonance layer 105 is different from the thickness of the second resonance layer 106.

In some embodiments, both the materials of the first resonance layer 105 and the second resonance layer 106 are inorganic materials. For example, the materials of the first resonance layer 105 and the second resonance layer 106 each includes at least one of silicon nitride and silicon oxynitride.

As first optional embodiments, the total thickness of the first resonance layer 105 and the second resonance layer 106 ranges from 1.7 μm (micrometer) to 2.1 μm. For example, the thickness of the first resonance layer 105 ranges from 1 μm to 1.2 μm; and the thickness of the second resonance layer 106 ranges from 0.7 μm to 0.9 μm.

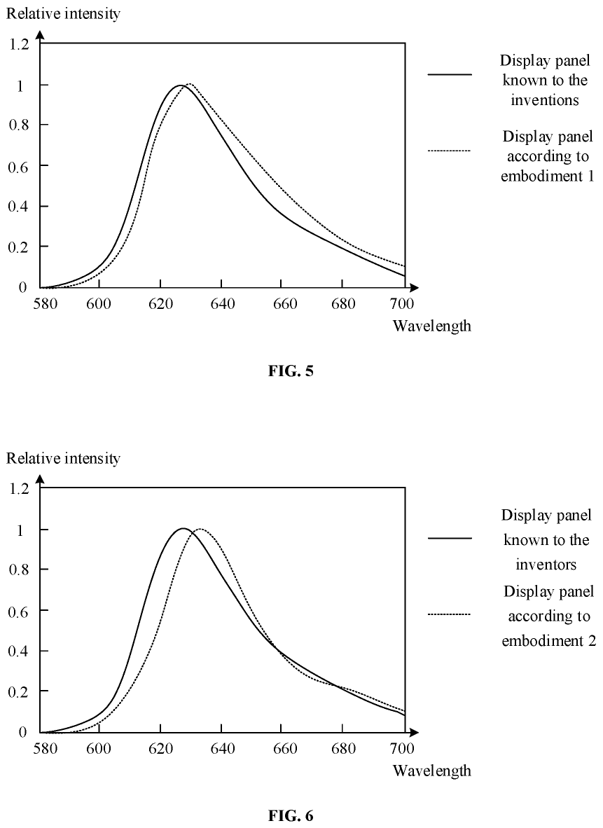

A schematic spectrum diagram shown in FIG. 5 is acquired after analog simulation is performed on the spectrum of red light emergent from a display panel known to the inventors and the spectrum of red light emergent from the display panel in the first optional embodiments of the present disclosure. In FIG. 5, a horizontal coordinate denotes a wavelength whose unit is nm; and a vertical coordinate denotes a relative intensity whose unit is an arbitrary unit (a.u.). Referring to FIG. 5, the spectrum of the red light emergent from the display panel in the first optional embodiments of the present disclosure is moved rightwards relative to the spectrum of the red light emergent from the display panel known to the inventors. In other words, the main wavelength of the red light emergent from the display panel in the first optional embodiments of the present disclosure becomes longer. In the display panel in the first optional embodiments of the present disclosure, the total thickness of the first resonance layer 105 and the second resonance layer 106 ranges from 1.7 μm to 2.1 μm. “Embodiment 1” represents the display panel in the first optional embodiments of the present disclosure.

In addition, referring to the following table 1, the chromaticity coordinate, the main wavelength, the spectral peak value, and the spectral half-peak width of the red light emergent from the display panel known to the inventors are acquired by analyzing the spectrum of the red light emergent from the display panel known to the inventors in FIG. 5; and the chromaticity coordinate, the main wavelength, the spectral peak value, and the spectral half-peak width of the red light emergent from the display panel in the first optional embodiments of the present disclosure are acquired by analyzing the spectrum of the red light emergent from the display panel in the first optional embodiments of the present disclosure.

TABLE 1

| | | Main | | |
|---|---|---|---|---|
| | Chromaticity | wavelength | Spectral peak | Spectral half- |
| Name | coordinate | (nm) | value (nm) | peak width (nm) |
| Display panel known | (0.689, 0.311) | 619 | 627 | 39 |
| to the inventors | | | | |
| Display panel | (0.694, 0.306) | 621 | 630 | 46 |
| according to | | | | |
| embodiment 1 | | | | |

Referring to the above table 1, it can be learned that the chromaticity coordinate of the red light emergent from the display panel in the first optional embodiments of the present disclosure is (0.694, 0.306), and the spectrum of the red light emergent from the display panel known to the inventors is (0.689, 0.311). In addition, the main wavelength, the spectral peak value, and the spectral half-peak width of the red light emergent from the display panel in the first optional embodiments of the present disclosure are all greater than those of the red light emergent from the display panel known to the inventors at a certain extent. The main wavelength of the red light emergent from the display panel in the first optional embodiments of the present disclosure is 621 nm which is greater than the main wavelength (619 nm) of the red light emergent from the display panel known to the inventors. This indicates that the addition of the first resonance layer 105 and the second resonance layer 106 can effectively increase the main wavelength of the red light emergent from the display panel 10.

As second optional embodiments, the total thickness of the first resonance layer 105 and the second resonance layer 106 ranges from 1.8 μm to 2.3 μm. This indicates that the total thickness of the first resonance layer 105 and the second resonance layer 106 in the second optional embodiments is 0.1 μm to 0.2 μm greater than the total thickness of the first resonance layer 105 and the second resonance layer 106 in the first optional embodiments. Optionally, only the thickness of the first resonance layer 105 is increased; or only the thickness of the second resonance layer 106 is increased; or both the thickness of the first resonance layer 105 and the thickness of the second resonance layer 106 are increased.

A schematic spectrum diagram shown in FIG. 6 is acquired after analog simulation is performed on the spectrum of red light emergent from a display panel known to the inventors and the spectrum of red light emergent from a display panel in the second optional embodiments of the present disclosure. In FIG. 6, a horizontal coordinate denotes a wavelength whose unit is nm; and a vertical coordinate denotes a relative intensity whose unit is an arbitrary unit. Referring to FIG. 6, the spectrum of red light emergent from the display panel in the second optional embodiments of the present disclosure is moved rightwards relative to the spectrum of the red light emergent from the display panel known to the inventors. In other words, the main wavelength of the red light emergent from the display panel in the second optional embodiments of the present disclosure becomes longer. In addition, the spectrum of the red light emergent from the display panel in the second optional embodiments of the present disclosure is narrower than the spectrum of the red light emergent from the display panel known to the inventors. The total thickness of the first resonance layer 105 and the second resonance layer 106 of the display panel in the second optional embodiments of the present disclosure ranges from 1.8 μm to 2.3 μm. “Embodiment 2” represents the display panel in the second optional embodiments of the present disclosure.

In addition, referring to the following table 2, the chromaticity coordinate, the main wavelength, the spectral peak value, and the spectral half-peak width of the red light emergent from the display panel known to the inventors are acquired by analyzing the spectrum of the red light emergent from the display panel known to the inventors in FIG. 6; and the chromaticity coordinate, the main wavelength, the spectral peak value, and the spectral half-peak width of the red light emergent from the display panel in the second optional embodiments of the present disclosure are acquired by analyzing the spectrum of the red light emergent from the display panel in the second optional embodiments of the present disclosure. The spectrum of the red light emergent from the display panel in the second optional embodiments of the present disclosure being narrower than the spectrum of the red light emergent from the display panel known to the inventors is represented by the difference between the spectral half-peak widths. A smaller spectral half-peak width indicates a narrower spectrum; and a greater spectral half-peak width indicates a wider spectrum.

TABLE 2

| | | Main | | |
|---|---|---|---|---|
| | Chromaticity | wavelength | Spectral peak | Spectral half- |
| Name | coordinate | (nm) | value (nm) | peak width (nm) |
| Display panel known | (0.689, 0.311) | 619 | 627 | 39 |
| to the inventors | | | | |
| Display panel | (0.696, 0.304) | 623 | 631 | 34 |
| according to | | | | |
| embodiment 2 | | | | |

Referring to the above table 2, it can be learned that the chromaticity coordinate of the red light emergent from the display panel in the second optional embodiments of the present disclosure is (0.696, 0.304). In addition, the main wavelength, the spectral peak value, and the spectral half-peak width of the red light emergent from the display panel in the second optional embodiments of the present disclosure are all greater than those of the red light emergent from the display panel known to the inventors at a certain extent. The main wavelength of the red light emergent from the display panel in the second optional embodiments of the present disclosure is 623 nm which is greater than the main wavelength (619 nm) of the red light emergent from the display panel known to the inventors. This indicates that the addition of the first resonance layer 105 and the second resonance layer 106 can effectively increase the main wavelength of the red light emergent from the display panel.

The spectrum of the red light emergent from the display panel in the second optional embodiments of the present disclosure being narrower than the spectrum of the red light emergent from the display panel known to the inventors is represented by the difference between the spectral half-peak widths. In addition, the spectral half-peak width of the red light emergent from the display panel in the second optional embodiments of the present disclosure is 34 nm which is less than the spectral half-peak width (39 nm) of the red light emergent from the display panel known to the inventors.

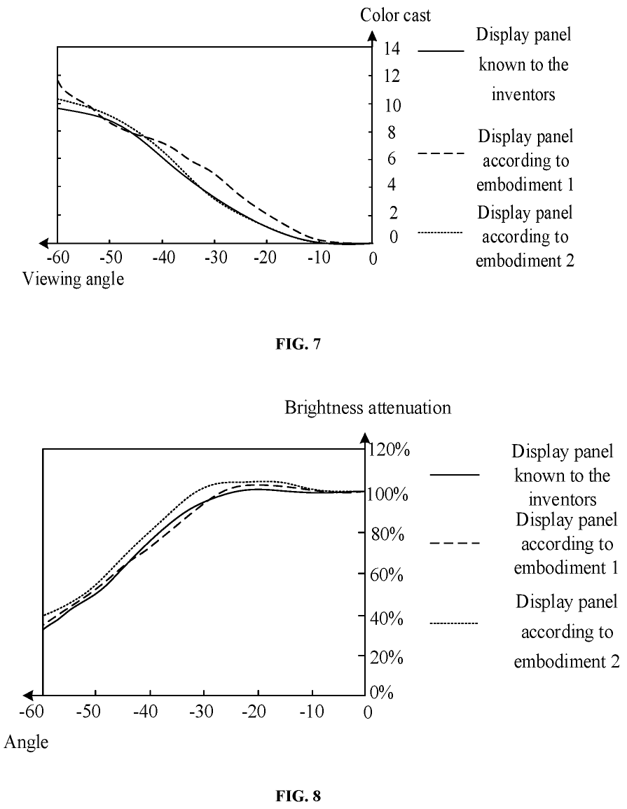

FIG. 7 is a schematic diagram of a color cast curve according to some embodiments of the present disclosure. Referring to FIG. 7, it can be learned that the color cast curve of the display panel in the first optional embodiments of the present disclosure and the color cast curve of the display panel in the second optional embodiments of the present disclosure differ slightly from the color cast curve of the display panel known to the inventors. In FIG. 7, a horizontal coordinate denotes a viewing angle which is configured to represent an included angle between a sight line of an observer and a plane where the display panel is. The unit of the viewing angle is °. A vertical coordinate denotes a color cast.

FIG. 8 is a schematic diagram of a brightness attenuation curve according to some embodiments of the present disclosure. Referring to FIG. 8, it can be learned that the brightness attenuation of the display panel in the first optional embodiments of the present disclosure and the brightness attenuation of the display panel in the second optional embodiments of the present disclosure are less than the brightness attenuation of the display panel known to the inventors. For example, when the viewing angle is small, the brightness attenuation curve of the display panel in the first optional embodiments of the present disclosure and the brightness attenuation curve of the display panel in the second optional embodiments of the present disclosure are slightly higher than the brightness attenuation curve of the display panel known to the inventors. In FIG. 8, a horizontal coordinate denotes a viewing angle which is configured to represent an included angle between a sight line of an observer and a plane where the display panel is. The unit of the viewing angle is “°”. A vertical coordinate denotes a brightness attenuation.

Referring to the following table 3, when the viewing angle is 50°, the color cast of the display panel in the first optional embodiments of the present disclosure is 8.6; the color cast of the display panel in the second optional embodiments of the present disclosure is 9.1; and the color cast of the display panel known to the inventors is 8.7. The viewing angle being 50° means the included angle between the sight line of the observer and the plane where the display panel is being 50°. In addition, the brightness attenuation of the display panel in the first optional embodiments of the present disclosure is 53%; the brightness attenuation of the display panel in the second optional embodiments of the present disclosure is 55%; and the brightness attenuation of the display panel known to the inventors is 51%.

TABLE 3

| | | Brightness | |
|---|---|---|---|
| Name | Color cast | attenuation | Viewing angle |
| Display panel known to the | 8.7 | 51% | 50 degrees |
| inventors | | | |
| Display panel according to | 8.6 | 53% | |
| embodiment 1 | | | |
| Display panel according to | 9.1 | 55% | |
| embodiment 2 | | | |

Referring to FIG. 2, it can be further learned that the total reflection electrode layer 102 includes a plurality of total reflection patterns 1021. The light-emitting layer 103 includes a plurality of light-emitting patterns 1031 which corresponds to the plurality of total reflection patterns 1021 in one-to-one correspondence. Each total reflection pattern 1021, a light-emitting pattern 1031 corresponding thereto, and the semi-reflection electrode layer 104 form one light-emitting unit.

In the embodiments of the present disclosure, the material of each light-emitting pattern 1031 includes a light-emitting host material and a doped guest material. The thickness of the light-emitting pattern 1031 in the red light-emitting unit ranges from 100 nm to 200 nm; and the refractive index of the light-emitting pattern 1031 ranges from 1.6 to 1.9.

The first resonance layer 105 includes a plurality of first resonance patterns 1051 which corresponds to the plurality of light-emitting units a in one-to-one correspondence. The orthographic projection of each first resonance pattern 1051 onto the base substrate 101 covers the orthographic projection of a light-emitting region of the corresponding light-emitting unit a onto the base substrate 101. The second resonance layer 106 includes a plurality of second resonance patterns 1061 which corresponds to the plurality of light-emitting units a in one-to-one correspondence. The orthographic projection of each second resonance pattern 1061 onto the base substrate 101 covers the orthographic projection of a light-emitting region of the corresponding light-emitting unit a onto the base substrate 101. The light-emitting region of each light-emitting unit a is a region where the light-emitting pattern 1031 of the light-emitting unit a is overlapped with both the total reflection pattern 1021 and the semi-reflection electrode layer 104.

The total thickness of one first resonance pattern 1051 and one second resonance pattern 1061 which cover the red light-emitting unit, the total thickness of one first resonance pattern 1051 and one second resonance pattern 1061 which cover the green light-emitting unit, and the total thickness of one first resonance pattern 1051 and one second resonance pattern 1061 which cover the blue light-emitting unit differ from each other.

Because light-emitting units of different colors emit light of different colors, the wavelengths of the light emitted by the light-emitting units of the different colors differ from each other. Therefore, the total thickness of two resonance patterns corresponding to one light-emitting unit a is different from the total thickness of two resonance patterns corresponding to a light-emitting unit a of a different color. This can meet intensity requirements for light emitted by light-emitting units a of different colors, and further guarantee the display effect of the display device. For example, the total thickness of two resonance patterns corresponding to one light-emitting unit a is different from the total thickness of two resonance patterns corresponding to a light-emitting unit a of a different color. Therefore, the wavelength of light emitted by the light-emitting units a can meet a corresponding color requirement in “European vehicle standards” via matching.

In some embodiments, the total thickness of the first resonance pattern and the second resonance pattern which cover the red light-emitting unit is greater than the total thickness of the first resonance pattern and the second resonance pattern which cover the green light-emitting unit; and the total thickness of the first resonance pattern and the second resonance pattern which cover the green light-emitting unit is greater than the total thickness of the first resonance pattern and the second resonance pattern which cover the blue light-emitting unit.

In some embodiments, there is another relationship among the total thicknesses of the first resonance patterns and the second resonance patterns which cover the light-emitting units of the different colors. Each of the total thicknesses is determined according to actual needs. For example, the total thickness of the first resonance pattern and the second resonance pattern which cover the green light-emitting unit is greater than the total thickness of the first resonance pattern and the second resonance pattern which cover the red light-emitting unit; and the total thickness of the first resonance pattern and the second resonance pattern which cover the red light-emitting unit is greater than the total thickness of the first resonance pattern and the second resonance pattern which cover the blue light-emitting unit.

Referring to FIG. 2, the display panel 10 further includes a planarization layer 107. The planarization layer 107 is disposed on the side, distal from the base substrate 101, of the second resonance layer 106. Because the total thickness of two resonance layers corresponding to one light-emitting unit a is different from the total thickness of two resonance layers corresponding to a light-emitting unit a of a different color, the thickness of the planarization layer 107 is designed as a great value to ensure that in each light-emitting unit a of the different color, the planarization layer 107 is provided on side, distal from the base substrate 101, of the two corresponding resonance patterns. Therefore, the flatness of the emergent interface of light emitted by each light-emitting unit a is high, which facilitates subsequent manufacture of another film layer. For example, the thickness of the planarization layer 107 ranges from 2 μm to 5 μm.

The material of the planarization layer 107 is an organic material having high transmittance. For example, the material is polyimide, acrylic, or the like.

Referring to FIG. 2, it can be further learned that the display panel 10 further includes a pixel definition layer 107. The pixel definition layer 107 is provided with a plurality of via holes. Each via hole exposes one total reflection pattern 1021. Each light-emitting pattern 1031 is disposed in one via hole, and be in contact with the total reflection pattern 1021 exposed by the via hole.

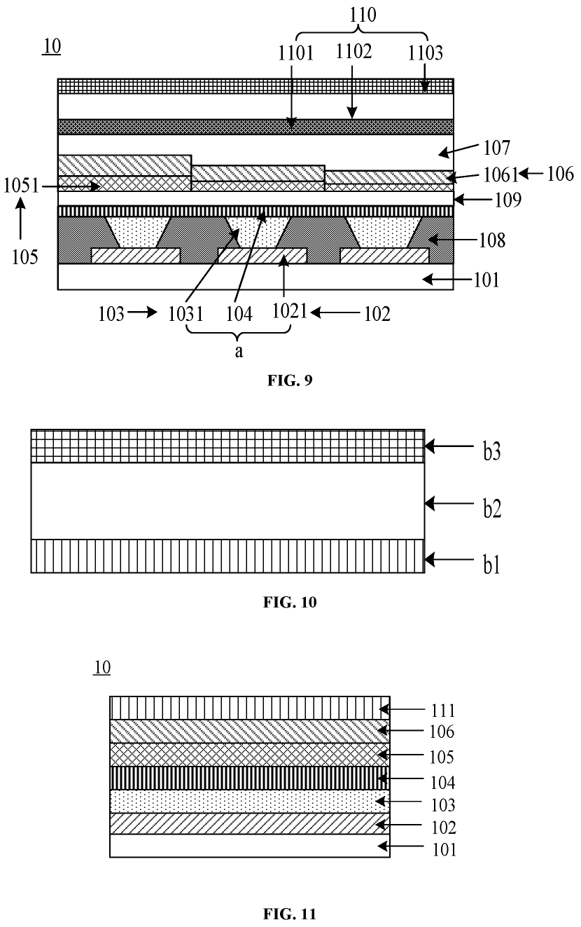

FIG. 9 is a schematic structural diagram of still another display panel according to some embodiments of the present disclosure. Referring to FIG. 9, it can be learned that the display panel 10 further includes a light-extracting layer 109 disposed between the semi-reflection electrode layer 104 and the first resonance layer 105. The light-extracting layer 109 is configured to transmit, to the first resonance layer 105, the light passing through the semi-reflection electrode layer 104. By disposing the light-extracting layer 109, the efficiency of transmitting, to the first resonance layer 105, the light passing through the semi-reflection electrode layer 104 can be improved. This can implement efficient extraction of the light emitted by the light-emitting units a, and reduce optical loss of the light caused by total reflection of an outer-layer interface.

In some embodiments, the thickness of the light-extracting layer 109 ranges from 150 nm to 300 nm; and the material of the light-extracting layer 109 is an organic material.

In the embodiments of the present disclosure, the refractive index of the first resonance layer 105 is less than the refractive index of the light-extracting layer 109; and the refractive index of the second resonance layer 106 is less than the refractive index of the planarization layer 107. For example, the refractive index of the light-extracting layer 109 ranges from 1.7 to 2.0; and the refractive index of the planarization layer 107 ranges from 1.9 to 2.1.

Referring to FIG. 9, it can be further learned that the display panel 10 further includes a packaging film layer 110. The packaging film layer 110 is disposed on the side, distal from the base substrate 101, of the second resonance layer 106. The packaging film layer 110 is configured to package the light-emitting units a, thereby preventing moisture from entering the light-emitting units a to adversely affect the display effect of the display panel 10.

The packaging film layer 110 includes a first packaging layer 1101, a second packaging layer 1102, and a third packaging layer 1103 which are sequentially laminated on the side distal from the base substrate 101. Both the materials of the first packaging layer 1101 and the third packaging layer 1103 include inorganic materials. The material of the second packaging layer 1102 includes an organic material. For example, the first packaging layer 1101 and the third packaging layer 1103 is made of one or more inorganic oxides of SiNx (silicon nitride), SiOx (silicon oxide), SiOxNy (silicon oxynitride), and the like. The second packaging layer 1102 is made of a resin material. The resin material is thermoplastic resin or thermosetting resin. The thermoplastic resin includes acrylic (PMMA) resin. The thermosetting resin includes epoxy resin.

In some embodiments, the second packaging layer 1102 is manufactured according to an ink jet printing (IJP) method; and the first packaging layer 1101 and the third packaging layer 1103 are manufactured according to a chemical vapor deposition (CVD) method.

The thickness of the first packaging layer 1101 ranges from 500 nm to 1500 nm; the thickness of the second packaging layer 1102 ranges from 8 μm to 15 μm; and the thickness of the third packaging layer 1103 ranges from 500 nm to 1500 nm. In addition, the refractive index of the first packaging layer 1101 ranges from 1.6 to 1.9; the refractive index of the second packaging layer 1102 ranges from 1.1 to 1.8; and the refractive index of the third packaging layer 1103 ranges from 1.6 to 1.9.

FIG. 10 is a schematic structural diagram of a total reflection electrode layer according to some embodiments of the present disclosure. Referring to FIG. 10, it can be learned that the total reflection electrode layer 102 includes a first film layer b1, a second film layer b2, and a third film layer b3 which are sequentially laminated in the direction distal from the base substrate 101.

In some embodiments, both the materials of the first film layer b1 and the third film layer b3 are conductive materials; and the reflectivity of the second film layer b2 is greater than a reflectivity threshold. For example, both the materials of the first film layer b1 and the third film layer b3 are indium tin oxide (ITO). The material of the second film layer b2 is silver (Ag). The reflectivity threshold is 80%. Both the thicknesses of the first film layer b1 and the third film layer b3 range from 5 nm to 10 nm; and the thickness of the second film layer b2 ranges from 80 nm to 200 nm. The total reflection electrode layer 102, having a characteristic of total reflection, is used as a lower reflection electrode layer of an internal resonant cavity of the light-emitting units a.

In the embodiments of the present disclosure, the material of the semi-reflection electrode layer 104 includes at least one of magnesium (Mg), silver (Ag), and aluminum (Al). The thickness of the semi-reflection electrode layer 104 ranges from 10 nm to 18 nm; the transmittance of the semi-reflection electrode layer 104 ranges from 50% to 60%; and the reflectivity of the semi-reflection electrode layer 104 ranges from 20% to 30%. The semi-reflection electrode layer 104, having characteristics of half reflection and half light transmission, is used as an upper reflection electrode layer of the internal resonant cavity of the light-emitting units a. The semi-reflection electrode layer 104 is used as a light-emitting electrode layer.

FIG. 11 is a schematic structural diagram of yet another display panel according to some embodiments of the present disclosure. Referring to FIG. 11, it can be learned that the display panel 10 further includes a third resonance layer 111 disposed on the side, distal from the base substrate 101, of the second resonance layer 106. The third resonance layer 111 is configured to reflect fifth light and allow sixth light to pass through. The fifth light and the sixth light are light passing through the semi-reflection electrode layer 104. In addition, the refractive index of the third resonance layer 111 is different from both the refractive index of the first resonance layer 105 and the refractive index of the second resonance layer 106.

The fifth light reflected by the third resonance layer 111 is different from the sixth light passing through the third resonance layer 111. In some embodiments, the included angle between the fifth light and the bearing surface of the base substrate 101 is different from the included angle between the sixth light and the bearing surface of the base substrate 101.

By disposing the third resonance layer 111 on the side, distal from the base substrate 101, of the second resonance layer 106, the mutual interference effect of reflected light can be further improved. Therefore, the intensity and chroma of emergent light can be further improved, thereby guaranteeing the display effect of the display device.

In some embodiments of the present disclosure, the refractive index of the third resonance layer 111 is greater than the refractive index of the second resonance layer 106. Because the third resonance layer 111 is more distal from the semi-reflection electrode layer 104 than the second resonance layer 106 is, light emergent from the semi-reflection electrode layer 104 first passes through the second resonance layer 106, and then pass through the third resonance layer 111. By designing the refractive index of the second resonance layer 106 to be less than the refractive index of the third resonance layer 111, light can be refracted conveniently by the interface between the third resonance layer 111 and the second resonance layer 106, thereby guaranteeing the display effect of the display device.

In some embodiments, the display panel 10 in the present disclosure includes two or three resonance layers. In some embodiments, the display panel 10 further includes a greater quantity of resonance layers. This is not limited in the embodiments of the present disclosure. Among the resonance layers included by the display panel 10, the refractive index of a resonance layer is positively correlated with the distance between the resonance layer and the semi-reflection electrode layer 104. In other words, the refractive index of a resonance layer which is at a longer distance from the semi-reflection electrode layer 104 is greater; and the refractive index of a resonance layer which is at a smaller distance from the semi-reflection electrode layer 104 is smaller.

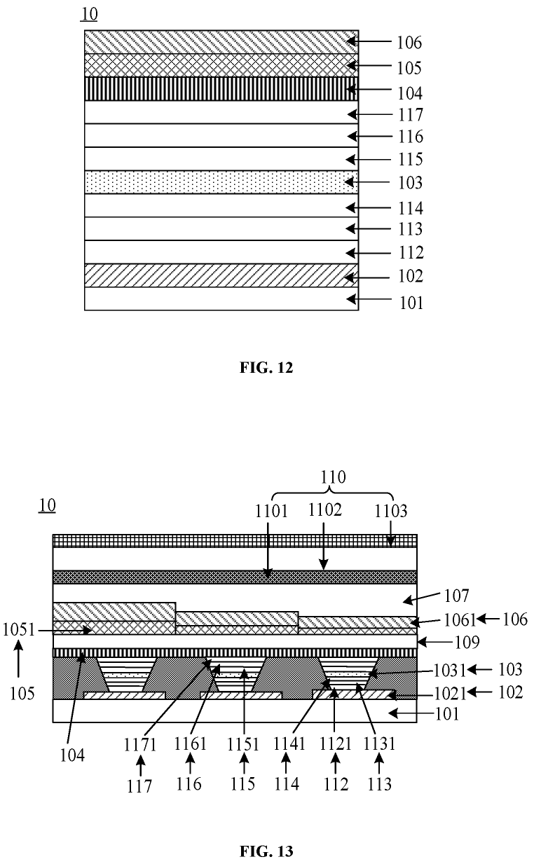

FIG. 12 is a schematic structural diagram of a display panel according to some embodiments of the present disclosure. Referring to FIG. 12, it can be learned that the display panel 10 further includes a hole injection layer 112, a hole transport layer 113, an electron barrier layer 114, a hole barrier layer 115, an electron transport layer 116, and an electron injection layer 117. The total reflection electrode layer 102, the hole injection layer 112, the hole transport layer 113, the electron barrier layer 114, the light-emitting layer 103, the hole barrier layer 115, the electron transport layer 116, the electron injection layer 117, and the semi-reflection electrode layer 104 are sequentially laminated in the direction distal from the base substrate 101.

Referring to FIG. 13, the hole injection layer 112 includes a plurality of hole injection patterns 1121 which corresponds to the plurality of total reflection patterns 1021 in one-to-one correspondence; the hole transport layer 113 includes a plurality of hole transport patterns 1131 which corresponds to the plurality of total reflection patterns 1021 in one-to-one correspondence; the electron barrier layer 114 includes a plurality of electron barrier patterns 1141 which corresponds to the plurality of total reflection patterns 1021 in one-to-one correspondence; the hole barrier layer 115 includes a plurality of hole barrier patterns 1151 which corresponds to the plurality of total reflection patterns 1021 in one-to-one correspondence; the electron transport layer 116 includes a plurality of electron transport patterns 1161 which corresponds to the plurality of total reflection patterns 1021 in one-to-one correspondence; and the electron injection layer 117 includes a plurality of electron injection patterns 1171 which corresponds to the plurality of total reflection patterns 1021 in one-to-one correspondence.

Each total reflection pattern 1021, a corresponding hole injection pattern 1121, a corresponding hole transport pattern 1131, a corresponding electron barrier pattern 1141, a corresponding light-emitting pattern 1031, a corresponding hole barrier pattern 1151, a corresponding electron transport pattern 1161, a corresponding electron injection pattern 1171, and the semi-reflection electrode layer 104 form one light-emitting unit.

The thickness of the hole transport layer 113 ranges from 80 nm to 120 nm; and the refractive index of the hole transport layer 113 ranges from 1.7 to 1.9. The thickness of the hole barrier layer 115 ranges from 3 nm to 10 nm; and the refractive index of the hole barrier layer 115 ranges from 1.6 to 1.8. The thickness of the electron transport layer 116 ranges from 20 nm to 50 nm; and the refractive index of the electron transport layer 116 ranges from 1.6 to 1.8.

In summary, the embodiments of the present disclosure provide a display panel. According to the display panel, a first resonance layer and a second resonance layer are disposed on a side, distal from a base substrate, of a semi-reflection electrode layer, such that after passing through the semi-reflection electrode layer, light emitted by a light-emitting layer is repeatedly reflected among the semi-reflection electrode layer, a total reflection electrode layer, the first resonance layer, and the second resonance layer. Because the display panel is provided with the first resonance layer and the second resonance layer, the mutual interference effect of light reflected in the display panel can be improved. Therefore, the intensity and chroma of light emergent from the display panel can be substantially improved and adjusted, thereby effectively improving the display effect of the display device.

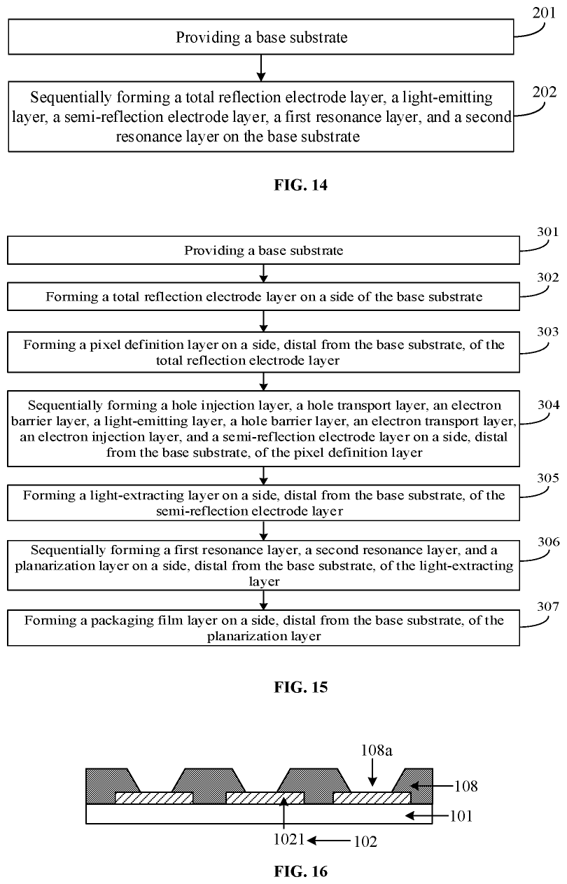

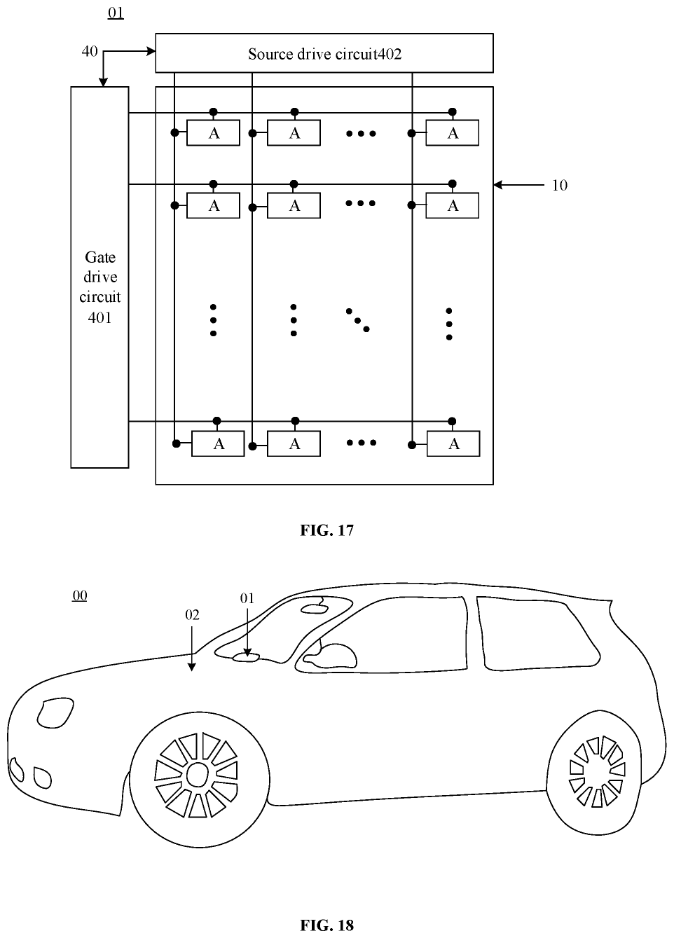

FIG. 14 is a flowchart of a method for manufacturing a display panel according to some embodiments of the present disclosure. The method is used to manufacture the display panel 10 provided in the foregoing embodiments. Referring to FIG. 14, the method includes the following steps.

In step 201, a base substrate is provided.

In the embodiments of the present disclosure, during manufacture of the display panel 10, the base substrate 101 is acquired first. The base substrate 101 is a flexible substrate. For example, the base substrate 101 is made of a flexible material. The flexible material is polyimide (PI).

In step 202, a total reflection electrode layer, a light-emitting layer, a semi-reflection electrode layer, a first resonance layer, and a second resonance layer are sequentially formed on the base substrate.

In the embodiments of the present disclosure, after the base substrate 101 is acquired, a total reflection electrode layer 102, a light-emitting layer 103, a semi-reflection electrode layer 104, a first resonance layer 105, and a second resonance layer 106 are sequentially formed on a side of the base substrate 101.

The light-emitting layer 103 in the display panel 10 emits light. The light is repeatedly reflected between the total reflection electrode layer 102 and the semi-reflection electrode layer 104 and is emergent from the semi-reflection electrode layer 104. In other words, the total reflection electrode layer 102 is configured to reflect the light emitted by the light-emitting layer 103; and the semi-reflection electrode layer 104 is configured to reflect the light emitted by the light-emitting layer 103, and allow the light to pass through.

The first resonance layer 105 and the second resonance layer 106 are formed on a side, distal from the base substrate 101, of the semi-reflection electrode layer 104. Therefore, after being repeatedly reflected between the semi-reflection electrode layer 104 and the total reflection electrode layer 102 and passing through the semi-reflection electrode layer 104, the light emitted by the light-emitting layer 103 is irradiated on the first resonance layer 105 and the second resonance layer 106. The first resonance layer 105 is configured to reflect first light and allow second light to pass through. The second resonance layer 106 is configured to reflect third light and allow fourth light to pass through. All of the first light, the second light, the third light, and the fourth light are the light passing through the semi-reflection electrode layer 104. The refractive index of the first resonance layer 105 is different from the refractive index of the second resonance layer 106.

The light emitted by the light-emitting layer 103 is repeatedly reflected between the semi-reflection electrode layer 104 and the total reflection electrode layer 102, such that an internal resonant micro-cavity effect is achieved. The first light reflected by the first resonance layer 105 is different from the second light passing through the first resonance layer 105. In some embodiments, the included angle between the first light and a bearing surface of the base substrate 101 is different from the included angle between the second light and the bearing surface of the base substrate 101. The third light reflected by the second resonance layer 106 is different from the fourth light passing through the second resonance layer 106. In some embodiments, the included angle between the third light and the bearing surface of the base substrate 101 is different from the included angle between the fourth light and the bearing surface of the base substrate 101.

Because the first resonance layer 105 and the second resonance layer 106 are disposed on the side, distal from the base substrate 101, of the semi-reflection electrode layer 104, and the refractive index of the first resonance layer 105 is different from the refractive index of the second resonance layer 106, the first light passing through the semi-reflection electrode layer 104 is reflected by the first resonance layer 105, and the third light passing through the semi-reflection electrode layer 104 is reflected by the second resonance layer 106. The reflected light is reflected again by the semi-reflection electrode layer 104, or enters space between the semi-reflection electrode layer 104 and the total reflection electrode layer 102 after passing through the semi-reflection electrode layer 104 and continue being reflected between the semi-reflection electrode layer 104 and the total reflection electrode layer 102. In other words, after being emergent from the semi-reflection electrode layer 104, the light continues being repeatedly reflected among the semi-reflection electrode layer 104, the total reflection electrode layer 102, the first resonance layer 105, and the second resonance layer 106. Being reflected by a great quantity of times, the light has a great mutual interference effect. Therefore, the intensity and chroma of emergent light can be substantially improved and adjusted, which can better improve the display effect of the display device. In other words, the display effect of the display device is better.

In summary, the embodiments of the present disclosure provide a method for manufacturing a display panel. According to the manufactured display panel, a first resonance layer and a second resonance layer are disposed on a side, distal from a base substrate, of a semi- reflection electrode layer, such that after passing through the semi-reflection electrode layer, light emitted by a light-emitting layer is repeatedly reflected among the semi-reflection electrode layer, a total reflection electrode layer, the first resonance layer, and the second resonance layer. Because the display panel is provided with the first resonance layer and the second resonance layer, the mutual interference effect of light reflected in the display panel can be improved. Therefore, the intensity and chroma of light emergent from the display panel can be substantially improved and adjusted, thereby effectively improving the display effect of the display device.

FIG. 15 is a flowchart of another method for manufacturing a display panel according to some embodiments of the present disclosure. The method is used to manufacture the display panel provided in the above embodiments. Referring to FIG. 15, the method includes the following steps.

In step 301, a base substrate is provided.

In the embodiments of the present disclosure, during the manufacture of the display panel 10, the base substrate 101 is acquired first. The base substrate 101 is a flexible substrate. For example, the base substrate 101 is made of a flexible material. The flexible material is polyimide.

In step 302, a total reflection electrode layer is formed on a side of the base substrate.

In the embodiments of the present disclosure, a first film layer b1, a second film layer b2, and a third film layer b3 of the total reflection electrode layer 102 are sequentially formed on the side of the base substrate 101 by a physical vapor deposition process. Both the materials of the first film layer b1 and the third film layer b3 are conductive materials; and the reflectivity of the second film layer b2 is greater than a reflectivity threshold. For example, both the materials of the first film layer b1 and the third film layer b3 are ITO (indium tin oxide). The material of the second film layer b2 is Ag. The reflectivity threshold is 80%. Both the thicknesses of the first film layer b1 and the third film layer b3 range from 5 nm to 10 nm; and the thickness of the second film layer b2 ranges from 80 nm to 200 nm. The total reflection electrode layer 102, having a characteristic of total reflection, is used as a lower reflection electrode layer of an internal resonant cavity of the light-emitting units a.

In step 303, a pixel definition layer is formed on a side, distal from the base substrate, of the total reflection electrode layer.

In the embodiments of the present disclosure, referring to FIG. 16, the pixel definition layer 108 is formed on the side, distal from the base substrate 101, of the total reflection electrode layer 102. The pixel definition layer 108 is provided with a plurality of via holes 108a. Each via hole 108a exposes one total reflection pattern 1021.

In step 304, a hole injection layer, a hole transport layer, an electron barrier layer, a light-emitting layer, a hole barrier layer, an electron transport layer, an electron injection layer, and a semi-reflection electrode layer are sequentially formed on a side, distal from the base substrate, of the pixel definition layer.

In the embodiments of the present disclosure, the hole injection layer 112, the hole transport layer 113, the electron barrier layer 114, the light-emitting layer 103, the hole barrier layer 115, the electron transport layer 116, the electron injection layer 117, and the semi-reflection electrode layer 104 are sequentially forming on the side, distal from the base substrate 101, of the pixel definition layer 108 by an evaporation process or an ink jet printing process.

The light-emitting layer 103 includes a plurality of light-emitting patterns 1031 which corresponds to the plurality of total reflection patterns 1021 in one-to-one correspondence; the hole injection layer 112 includes a plurality of hole injection patterns 1121 which corresponds to the plurality of total reflection patterns 1021 in one-to-one correspondence; the hole transport layer 113 includes a plurality of hole transport patterns 1131 which corresponds to the plurality of total reflection patterns 1021 in one-to-one correspondence; the electron barrier layer 114 includes a plurality of electron barrier patterns 1141 which corresponds to the plurality of total reflection patterns 1021 in one-to-one correspondence; the hole barrier layer 115 includes a plurality of hole barrier patterns 1151 which corresponds to the plurality of total reflection patterns 1021 in one-to-one correspondence; the electron transport layer 116 includes a plurality of electron transport patterns 1161 which corresponds to the plurality of total reflection patterns 1021 in one-to-one correspondence; and the electron injection layer 117 includes a plurality of electron injection patterns 1171 which corresponds to the plurality of total reflection patterns 1021 in one-to-one correspondence.

In addition, the material of the semi-reflection electrode layer 104 includes at least one of magnesium (Mg), silver (Ag), and aluminum (Al). The thickness of the semi-reflection electrode layer 104 ranges from 10 nm to 18 nm; the transmittance of the semi-reflection electrode layer 104 ranges from 50% to 60%; and the reflectivity of the semi-reflection electrode layer 104 ranges from 20% to 30%. The semi-reflection electrode layer 104, having characteristics of half reflection and half light transmission, is used as an upper reflection electrode layer of the internal resonant cavity of the light-emitting units a. The semi-reflection electrode layer 104 is used as a light-emitting electrode layer.

In step 305, a light-extracting layer is formed on a side, distal from the base substrate, of the semi-reflection electrode layer.

In the embodiments of the present disclosure, the light-extracting layer 109 is formed on the side, distal from the base substrate 101, of the semi-reflection electrode layer 104. The light-extracting layer 109 is configured to transmit, to the first resonance layer 105, the light passing through the semi-reflection electrode layer 104. The material of the light-extracting layer 109 is an organic material. The thickness of the light-extracting layer 109 ranges from 150 nm to 300 nm.

In step 306, a first resonance layer, a second resonance layer, and a planarization layer are sequentially formed on a side, distal from the base substrate, of the light-extracting layer.

In the embodiments of the present disclosure, the first resonance layer 105, the second resonance layer 106, and the planarization layer 107 are sequentially formed on the side, distal from the base substrate 101, of the light-extracting layer 109.

The first resonance layer 105 includes a plurality of first resonance patterns 1051 which corresponds to the plurality of light-emitting units a in one-to-one correspondence. The orthographic projection of each first resonance pattern 1051 onto the base substrate 101 covers the orthographic projection of a light-emitting region of the corresponding light-emitting unit a onto the base substrate 101. The second resonance layer 106 includes a plurality of second resonance patterns 1061 which corresponds to the plurality of light-emitting units a in one-to-one correspondence. The orthographic projection of each second resonance pattern 1061 onto the base substrate 101 covers the orthographic projection of a light-emitting region of the corresponding light-emitting unit a onto the base substrate 101.

In some embodiments, the refractive index of the first resonance layer 105 is less than the refractive index of the light-extracting layer 109; and the refractive index of the second resonance layer 106 is less than the refractive index of the planarization layer 107. For example, the refractive index of the light-extracting layer 109 ranges from 1.7 to 2.0; and the refractive index of the planarization layer 107 ranges from 1.9 to 2.1.

In addition, the thickness of the planarization layer 107 ranges from 2 μm to 5 μm. The material of the planarization layer 107 is an organic material having high transmittance. For example, the material is polyimide, acrylic, or the like.

In step 307, a packaging film layer is formed on a side, distal from the base substrate, of the planarization layer.

In the embodiments of the present disclosure, a first packaging layer 1101, a second packaging layer 1102, and a third packaging layer 1103 are sequentially formed on the side, distal from the base substrate 101, of the planarization layer 107. The second packaging layer 1102 is manufactured according to an IJP method; and the first packaging layer 1101 and the third packaging layer 1103 are manufactured according to a CVD method.

In summary, the embodiments of the present disclosure provide a method for manufacturing a display panel. According to the manufactured display panel, a first resonance layer and a second resonance layer are disposed on a side, distal from a base substrate, of a semi-reflection electrode layer, such that after passing through the semi-reflection electrode layer, light emitted by a light-emitting layer is repeatedly reflected among the semi-reflection electrode layer, a total reflection electrode layer, the first resonance layer, and the second resonance layer. Because the display panel is provided with the first resonance layer and the second resonance layer, the mutual interference effect of light reflected in the display panel can be improved. Therefore, the intensity and chroma of light emergent from the display panel can be substantially improved and adjusted, thereby effectively improving the display effect of the display device.

FIG. 16 is a schematic structural diagram of a display device according to some embodiments of the present disclosure. Referring to FIG. 16, the display device 01 includes a drive circuit 40 and the display panel 10 provided in the above embodiments. The drive circuit is connected to a plurality of pixels A in the display panel 10, and is configured to provide drive signals for the plurality of pixels A. Each pixel A includes the light-emitting unit a in the above embodiments and a pixel circuit connected to the light-emitting unit a.

In some embodiments, referring to FIG. 16, the drive circuit 40 includes a gate drive circuit 401 and a source drive circuit 402. The gate drive circuit 401 is connected to each row of pixels A in the display panel 10 via a gate line, and is configured to provide a gate drive signal for each row of pixels A. The source drive circuit 402 is connected to each column of pixels A in the display panel 10 via a data line, and is configured to provide a data signal for each column of pixels A.

In some embodiments, the display device 01 is any product or component with a display function, such as an OLED display device, a quantum dot light-emitting diode (QLED) display device, electronic paper, a mobile phone, a tablet computer, a TV, a monitor, a notebook computer, a digital photo frame, or a navigator.

FIG. 18 is a schematic structural diagram of a vehicle according to some embodiments of the present disclosure. Referring to FIG. 18, the vehicle includes a vehicle body 02 and the display device 01 provided in the above embodiments and disposed in the vehicle body 02.

In a display panel 10 of the display device 01, a first resonance layer and a second resonance layer are disposed on a side, distal from a base substrate, of a semi-reflection electrode layer, such that after passing through the semi-reflection electrode layer, light emitted by a light-emitting layer is repeatedly reflected among the semi-reflection electrode layer, a total reflection electrode layer, the first resonance layer, and the second resonance layer. Therefore, the mutual interference effect of reflected light is great, which can obviously improve and adjust the intensity and chroma of emergent light, and well improve the display effect of the display device 01. In addition, the wavelength of red light emergent from the display panel 10 reaches 623 nm which can meet a requirement for the chroma of light emergent from a display panel in “European vehicle standards”.

The above are merely exemplary embodiments of the present disclosure, but are not intended to limit the present disclosure. Any modifications, equivalent replacements and improvements made within the spirits and principles of the present disclosure shall all fall in the protection scope of the present disclosure.

What is claimed is:

1. A display panel, comprising:
a base substrate; and
a total reflection electrode layer, a light-emitting layer, a semi-reflection electrode layer, a first resonance layer, and a second resonance layer which are sequentially laminated in a direction distal from the base substrate,
wherein the first resonance layer is configured to reflect first light and allow second light to pass through; the second resonance layer is configured to reflect third light and allow fourth light to pass through; all of the first light, the second light, the third light, and the fourth light are light passing through the semi-reflection electrode layer; and a refractive index of the first resonance layer is different from a refractive index of the second resonance layer.

2. The display panel according to claim 1, wherein the refractive index of the first resonance layer is less than the refractive index of the second resonance layer.

3. The display panel according to claim 2, wherein the refractive index of the first resonance layer ranges from 1.6 to 1.7; and the refractive index of the second resonance layer ranges from 1.8 to 1.9.

4. The display panel according to claim 1, wherein there is at least one of:
a material of the first resonance layer is different from a material of the second resonance layer; or
a thickness of the first resonance layer is different from a thickness of the second resonance layer.

5. (canceled)

6. The display panel according to claim 4, wherein the materials of the first resonance layer and the second resonance layer each comprise at least one of silicon nitride and silicon oxynitride.

7. The display panel according to claim 4, wherein there is one of:
a total of the thickness of the first resonance layer and the thickness of the second resonance layer ranges from 1.7 μm to 2.1 μm; or a total of the thickness of the first resonance layer and the thickness of the second resonance layer ranges from 1.8 μm to 2.3 μm.

8-9. (canceled)

10. The display panel according to claim 1, wherein the display panel comprises a plurality of light-emitting units; the total reflection electrode layer comprises a plurality of total reflection patterns; and the light-emitting layer comprises a plurality of light-emitting patterns which corresponds to the plurality of total reflection patterns in one-to-one correspondence; and
each total reflection pattern, a light-emitting pattern corresponding to the total reflection pattern, and the semi-reflection electrode layer form one light-emitting unit.

11. The display panel according to claim 10, wherein the plurality of light-emitting units comprise a red light-emitting unit, a green light-emitting unit, and a blue light-emitting unit; the first resonance layer comprises a plurality of first resonance patterns which corresponds to the plurality of light-emitting units in one-to-one correspondence; an orthographic projection of each first resonance pattern onto the base substrate covers an orthographic projection of a light-emitting region of a light-emitting unit corresponding to first resonance pattern onto the base substrate; the second resonance layer comprises a plurality of second resonance patterns which corresponds to the plurality of light-emitting units in one-to-one correspondence; and an orthographic projection of each second resonance pattern onto the base substrate covers an orthographic projection of a light-emitting region of a light-emitting unit corresponding to the second resonance pattern onto the base substrate; and
a total thickness of one first resonance pattern and one second resonance pattern which cover the red light-emitting unit, a total thickness of one first resonance pattern and one second resonance pattern which cover the green light-emitting unit, and a total thickness of one first resonance pattern and one second resonance pattern which cover the blue light-emitting unit differ from each other.

12. (canceled)

13. The display panel according to claim 1, wherein the display panel further comprises a light-extracting layer disposed between the semi-reflection electrode layer and the first resonance layer; and
the light-extracting layer is configured to transmit, the light passing through the semi-reflection electrode layer, to the first resonance layer.

14. The display panel according to claim 13, wherein a thickness of the light-extracting layer ranges from 150 nm to 300 nm; and the light-extracting layer is made of an organic material.

15. The display panel according to claim 13, wherein the display panel further comprises a planarization layer disposed on a side, distal from the base substrate, of the second resonance layer; and
the refractive index of the first resonance layer is less than a refractive index of the light-extracting layer and the refractive index of the second resonance layer; and the refractive index of the second resonance layer is less than a refractive index of the planarization layer.

16. The display panel according to claim 15, wherein the refractive index of the light-extracting layer ranges from 1.7 to 2.0; and the refractive index of the planarization layer ranges from 1.9 to 2.1.

17. The display panel according to claim 1, wherein the display panel further comprises a packaging layer; and
the packaging film layer is disposed on the side, distal from the base substrate, of the second resonance layer.

18. The display panel according to claim 17, wherein the packaging film layer comprises a first packaging layer, a second packaging layer, and a third packaging layer which are sequentially laminated in the direction distal from the base substrate;
the first packaging layer is made of an inorganic material; a thickness of the first packaging layer ranges from 500 nm to 1500 nm; and a refractive index of the first packaging layer ranges from 1.6 to 1.9;
the second packaging layer is made of organic material; a thickness of the second packaging layer ranges from 8 μm to 15 μm; and a refractive index of the second packaging layer ranges from 1.1 to 1.8; and
the third packaging layer is made of an inorganic material; a thickness of the third packaging layer ranges from 500 nm to 1500 nm; and a refractive index of the third packaging layer ranges from 1.6 to 1.9.

19. The display panel according to claim 1, wherein the total reflection electrode layer comprises a first film layer, a second film layer, and a third film layer which are sequentially laminated in the direction distal from the base substrate; and
both the first film layer and the third film layer are made of indium tin oxide; and a reflectivity of the second film layer is greater than 80%.

20. The display panel according to claim 1, wherein a reflectivity of the semi-reflection electrode layer ranges from 20% to 30%; and a material of the semi-reflection electrode layer comprises at least one of magnesium, silver, and aluminum.

21. The display panel according to claim 1, wherein the display panel further comprises a third resonance layer disposed on the side, distal from the base substrate, of the second resonance layer; and
the third resonance layer is configured to reflect fifth light and allow sixth light to pass through, wherein the fifth light and the sixth light are light passing through the semi-reflection electrode layer; and a refractive index of the third resonance layer is different from both the refractive index of the first resonance layer and the refractive index of the second resonance layer.

22. A method for manufacturing a display panel, comprising:
providing a base substrate; and
sequentially forming a total reflection electrode layer, a light-emitting layer, a semi-reflection electrode layer, a first resonance layer, and a second resonance layer in a direction distal from the base substrate,
wherein the first resonance layer is configured to reflect first light and allow second light to pass through; the second resonance layer is configured to reflect third light and allow fourth light to pass through; all of the first light, the second light, the third light, and the fourth light are light passing through the semi-reflection electrode layer; and a refractive index of the first resonance layer is different from a refractive index of the second resonance layer.

23. A display device, comprising a power supply assembly and a display panel wherein the display panel comprises:
a base substrate; and
a total reflection electrode layer, a light-emitting layer, a semi-reflection electrode layer, a first resonance layer, and a second resonance layer which are sequentially laminated in a direction distal from the base substrate,
wherein the first resonance layer is configured to reflect first light and allow second light to pass through; the second resonance layer is configured to reflect third light and allow fourth light to pass through; all of the first light, the second light, the third light, and the fourth light are light passing through the semi-reflection electrode layer; and a refractive index of the first resonance layer is different from a refractive index of the second resonance layer; and
the power supply assembly is configured to supply power to the display panel.

24. A vehicle, comprising a vehicle body and the display device as defined in claim 23 and disposed in the vehicle body.
